(19) United States
(12) Patent Application Publication
(10) Pub. No.: US 2007/0194677 A1
(43) Pub. Date: Aug. 23, 2007

(54) Structure and method for improving contact resistance in an organic light emitting diode integrated with a color filter

(75) Inventors: Yu-Jung Liu, Kaohsiung City (TW); Yi-Hsun Huang, Hsinchu City (TW); Yung-Hui Yeh, Hsinchu City (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 11/651,448

(22) Filed: Jan. 10, 2007

(30) Foreign Application Priority Data
Feb. 23, 2006 (TW) 095106025

(51) Int. Cl. H01L 51/52; H01L 51/56

(52) U.S. Cl. 313/112; 313/506; 313/509; 257/98; 257/E51.002; 438/29

(57) ABSTRACT

A structure and method for improving contact resistance in an organic light emitting diode integrated with a color filter, the structure and method mainly utilize a metal to be filled in a contact well on a source/drain metal layer or in a contact well corresponding to the position of the source/drain metal layer on a poly-silicon island to effectively reduce the contact resistance between pixel electrode and thin film transistor, therefore color display quality of the organic light emitting diode is improved.

### FIELD OF THE INVENTION

The present invention relates to a structure and method for improving contact resistance in an organic light emitting diode integrated with a color filter, more particularly to a structure and method utilizing a metal to be filled in a contact well on a source/drain metal layer or in a contact well corresponding to the position of the source/drain metal layer on a poly-silicon island to effectively reduce the contact resistance between pixel electrode and thin film transistor, therefore color display quality of the organic light emitting diode is improved.

### BACKGROUND OF THE INVENTION

The design for organic light emitting display (OLED) has developed to using a single white light source integrated with a color filter for realizing high definition image quality and avoiding decays of different colors, thus resolution and size of the display has been greatly increased. The process of manufacturing an OLED integrated with a color filter usually utilizes a structure of color filter on array (COA) and uses a white light source of bottom-emission organic light emitting display (OLED). However, surface of the color filter after solidification is rather rough and a planarization layer is needed to be added on the color filter. Thus, thickness of the display is increased and contact resistance of pixel electrode is also increased so that electric conductivity between source/drain metal layer and bottom electrode of the organic light emitting diode is worse when the thin film transistor operates. Therefore, it is easy to cause the metal burned down such that the organic light emitting diode can not operate normally.

A conventional structure of an organic light emitting diode integrated with a color filter is disclosed in U.S. Pat. No. 6,515,428 entitled “Pixel Structure of an Organic Light Emitting Diode Display Device and its Manufacturing Method.” For reducing surface roughness of the conventional structure, a planarization layer is added on the color filter as shown in FIG. 1. In FIG. 1, a poly-silicon island 120 is formed on a substrate 110, an insulating oxide layer 130 is formed on the substrate 110 to cover the poly-silicon island 120, a gate metal layer 135 corresponding to the central position of the poly-silicon island 120 is formed on the insulating oxide layer 130, a dielectric layer 140 is formed on the insulating oxide layer 130 to cover the gate metal layer 135, a source/drain metal layer 150 is formed on the dielectric layer 140 and a part of the source/drain metal layer 150 penetrates the dielectric layer 140 and the insulating oxide layer 130 to connect with corresponding positions of the poly-silicon island 120, a color filter 160 is formed on the source/drain metal layer 150, a planarization layer 170 is formed on the color filter 160, and a pixel electrode layer 180 is formed on the planarization layer 170 and a part of the pixel electrode layer 180 penetrates the planarization layer 170 and the color filter 160 to form a contact well and to connect with the source/drain metal layer 150. In this conventional structure, because the total thickness of the color filter 160 and the planarization layer 170 is too large, the pixel electrode layer 180 needs to be filled in a deeper contact well. Metal will become inferior when current flows therein to generate heat, such that the metal contact resistance between the pixel electrode layer 180 and thin film transistor will become too large, i.e. the electric conductivity between the source/drain metal and the pixel electrode is worse when the thin film transistor operates. Therefore, it is easy to cause the metal burned down such that the organic light emitting diode can not operate normally, which condition is also a main factor causing unbalanced color of the organic light emitting diode display.

To solve the large metal contact resistance problem between pixel electrode and thin film transistor due to the large total thickness of the color filter and the planarization layer in prior art structure and method for organic light emitting diode integrated with a color filter, the present invention provides a structure and method for improving contact resistance in an organic light emitting diode integrated with a color filter, the structure and method mainly utilize a metal to be filled in a contact well on a source/drain metal layer or in a contact well corresponding to the position of the source/drain metal layer on a poly-silicon island to effectively reduce the contact resistance between pixel electrode and thin film transistor, therefore color display quality of the organic light emitting diode is improved.

### SUMMARY OF THE INVENTION

The primary objective of the present invention is to provide a structure for improving contact resistance of an organic light emitting diode integrated with a color filter, so as to effectively reduce the contact resistance between pixel electrode and thin film transistor, therefore color display quality of the organic light emitting diode is improved.

The secondary objective of the present invention is to provide a method for improving contact resistance of an organic light emitting diode integrated with a color filter, so as to effectively reduce the contact resistance between pixel electrode and thin film transistor, therefore color display quality of the organic light emitting diode is improved.

To achieve the foregoing objectives, the present invention provides a structure and method for improving contact resistance in an organic light emitting diode integrated with a color filter, the structure and method mainly utilize a metal to be filled in a contact well on a source/drain metal layer or in a contact well corresponding to the position of the source/drain metal layer on a poly-silicon island to effectively reduce the contact resistance between pixel electrode and thin film transistor, therefore color display quality of the organic light emitting diode is improved.

To make the examiner easier to understand the objectives, structure, innovative features, and function of the invention, preferred embodiments together with accompanying drawings are illustrated for the detailed description of the invention.

### BRIEF DESCRIPTION OF THE DRAWINGS

FIG. 1 is a structure diagram of a prior art organic light emitting diode integrated with a color filter.

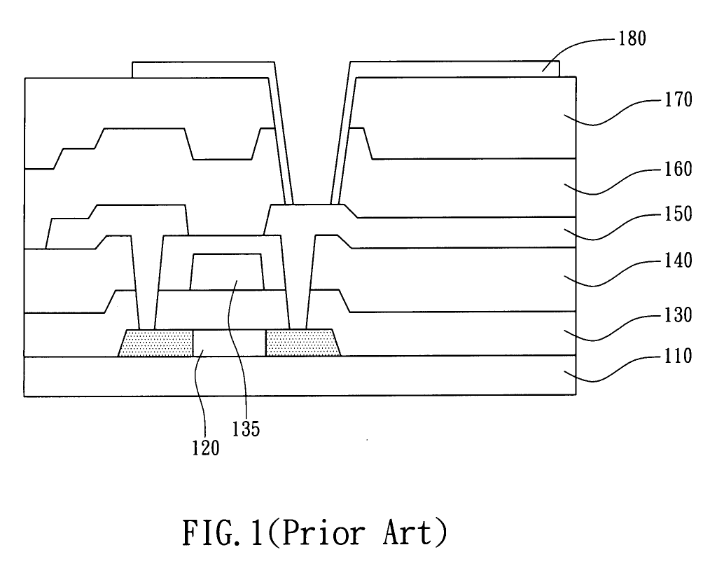

FIG. 2 is a structure diagram of the first embodiment of organic light emitting diode integrated with a color filter of the present invention.

FIG. 3 is a structure diagram of the second embodiment of organic light emitting diode integrated with a color filter of the present invention.

FIG. 4 is a structure diagram of the third embodiment of organic light emitting diode integrated with a color filter of the present invention.

### DESCRIPTION OF THE PREFERRED EMBODIMENT

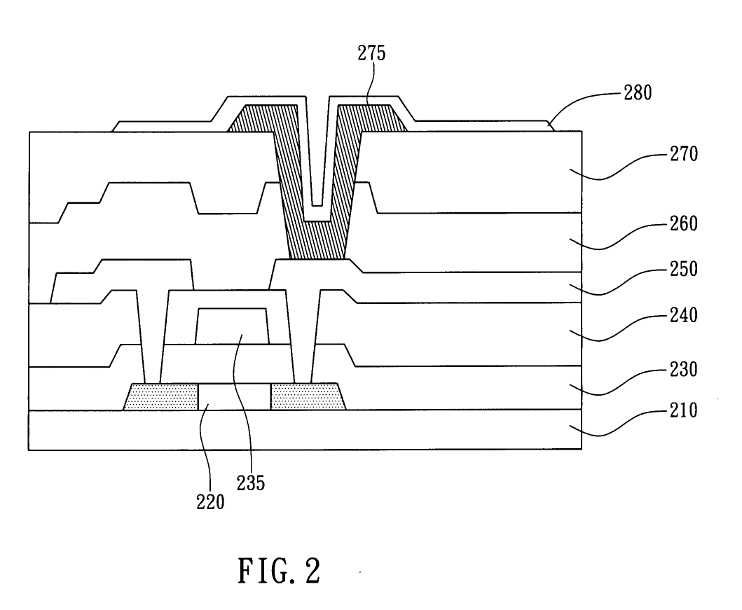

FIG. 2 is a structure diagram of the first embodiment of the present invention for improving contact resistance of an organic light emitting diode integrated with a color filter. In FIG. 2, a poly-silicon island 220 is formed on a substrate 210, an insulating oxide layer 230 is formed on the substrate 210 to cover the poly-silicon island 220, a gate metal layer 235 corresponding to the central position of the poly-silicon island 220 is formed on the insulating oxide layer 230, a dielectric layer 240 is formed on the insulating oxide layer 230 to cover the gate metal layer 235, a source/drain metal layer 250 is formed on the dielectric layer 240 and a part of the source/drain metal layer 250 penetrates the dielectric layer 240 and the insulating oxide layer 230 to connect with corresponding positions of the poly-silicon island 220, a color filter 260 is formed on the source/drain metal layer 250, a planarization layer 270 is formed on the color filter 260, a metal layer 275 is formed on the planarization layer 270 and a part of the metal layer 275 penetrates the planarization layer 270 and the color filter 260 to connect with the source/drain metal layer 250, and a pixel electrode layer 280 is formed on the metal layer 275 and the planarization layer 270. The structure of the first embodiment of the present invention can be used to improve that of the above-mentioned prior art. By filling a metal layer in the contact well penetrating the planarization layer and the color filter, metal contact resistance between pixel electrode layer and thin film transistor in the first embodiment of the present invention can be greatly reduced thus color display quality and useful life of the organic light emitting diode is improved. In addition, since the color filter is generally a negative photoresist, the photomask pattern for defining the color filter is the same with the metal pattern for filling in the contact well. Therefore, the present invention merely uses one common photomask of the color filter and needs no additional photomask.

The method of manufacturing the first embodiment of the present invention for improving contact resistance of an organic light emitting diode integrated with a color filter, comprising the following steps:
(a) providing a substrate;
(b) forming a poly-silicon island on the substrate;
(c) forming an insulating oxide layer on the substrate to cover the poly-silicon island;
(d) forming a gate metal layer corresponding to the central position of the poly-silicon island on the insulating oxide layer;
(e) forming a dielectric layer on the insulating oxide layer to cover the gate metal layer;
(f) forming multiple contact wells on the dielectric layer, wherein the contact wells penetrate the dielectric layer and the insulating oxide layer;
(g) forming a source/drain metal layer on the dielectric layer, wherein a part of the source/drain metal layer fills the contact wells and penetrates the dielectric layer and the insulating oxide layer to connect with corresponding positions of the poly-silicon island;
(h) forming a color filter on the source/drain metal layer;
(i) forming a planarization layer on the color filter;
(j) forming a contact well on the planarization layer, wherein the contact well penetrates the planarization layer and the color filter;
(k) forming a metal layer on the planarization layer, wherein a part of the metal layer fills the contact well and penetrates the planarization layer and the color filter to connect with corresponding position of the source/drain metal layer; and
(l) forming a pixel electrode layer on the metal layer and the planarization layer.

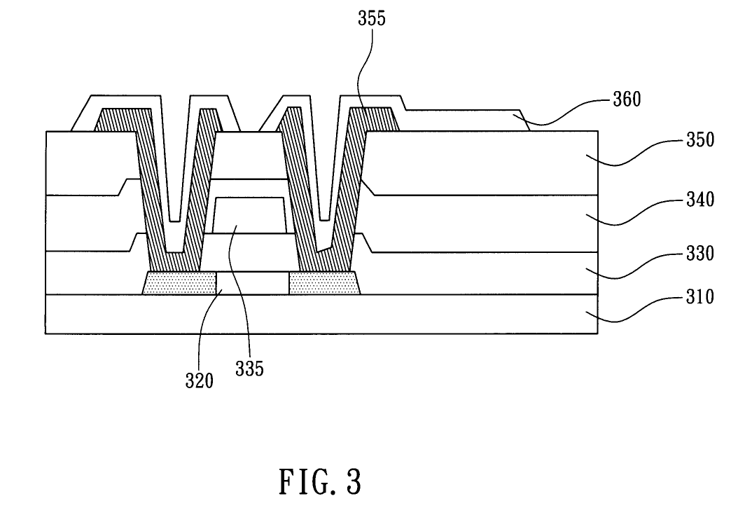

FIG. 3 is a structure diagram of the second embodiment of the present invention for improving contact resistance of an organic light emitting diode integrated with a color filter. In FIG. 3, a poly-silicon island 320 is formed on a substrate 310, an insulating oxide layer 330 is formed on the substrate 310 to cover the poly-silicon island 320, a gate metal layer 335 corresponding to the central position of the poly-silicon island 320 is formed on the insulating oxide layer 330, a color filter 340 is formed on the insulating oxide layer 330 to cover the gate metal layer 335, a planarization layer 350 is formed on the color filter 340, a metal layer 355 is formed on the planarization layer 350 and a part of the metal layer 355 penetrates the planarization layer 350, the color filter 340 and the insulating oxide layer 330 to connect with corresponding positions of the poly-silicon island 320, and a pixel electrode layer 360 is formed on the metal layer 355 and the planarization layer 350. In this second embodiment of the present invention, the pixel electrode layer 360 also has function of a source/drain metal layer simultaneously. The structure of the second embodiment of the present invention also can be used to improve that of the above-mentioned prior art. By filling a metal layer in the contact well penetrating the planarization layer, the color filter and the insulating oxide layer, metal contact resistance between pixel electrode layer and thin film transistor in the second embodiment of the present invention can be greatly reduced thus color display quality and useful life of the organic light emitting diode is improved. As mentioned previously, since the color filter is generally a negative photoresist, the photomask pattern for defining the color filter is the same with the metal pattern for filling in the contact well. Therefore, the present invention merely uses one common photomask of the color filter and needs no additional photomask.

The method of manufacturing the second embodiment of the present invention for improving contact resistance of an organic light emitting diode integrated with a color filter, comprising the following steps:
(a) providing a substrate;
(b) forming a poly-silicon island on the substrate;
(c) forming an insulating oxide layer on the substrate to cover the poly-silicon island;
(d) forming a gate metal layer corresponding to the central position of the poly-silicon island on the insulating oxide layer;
(e) forming a color filter on the insulating oxide layer to cover the gate metal layer;
(f) forming a planarization layer on the color filter;
(g) forming multiple contact wells on the planarization layer, wherein the contact wells penetrate the planarization layer, the color filter and the insulating oxide layer;
(h) forming a metal layer on the planarization layer, wherein a part of the metal layer fills the contact wells and penetrates the planarization layer, the color filter and the insulating oxide layer to connect with corresponding positions of the poly-silicon island; and
(i) forming a pixel electrode layer on the planarization layer.

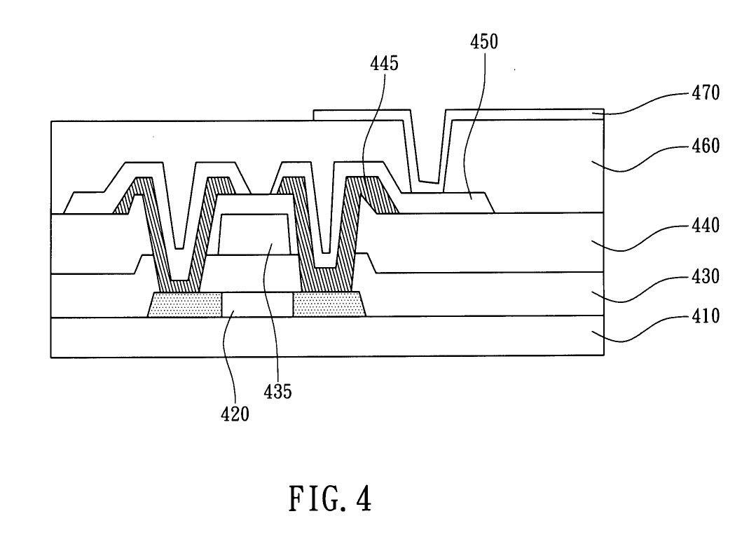

FIG. 4 is a structure diagram of the third embodiment of the present invention for improving contact resistance of an organic light emitting diode integrated with a color filter. In FIG. 4, a poly-silicon island 420 is formed on a substrate 410, an insulating oxide layer 430 is formed on the substrate 410 to cover the poly-silicon island 420, a gate metal layer 435 corresponding to the central position of the poly-silicon island 420 is formed on the insulating oxide layer 430, a color filter 440 is formed on the insulating oxide layer 430 to cover the gate metal layer 435, a metal layer 445 is formed on the color filter 440 and a part of the metal layer 445 penetrates the color filter 440 and the insulating oxide layer 430 to connect with corresponding positions of the poly-silicon island 420, a source/drain metal layer 450 is formed on the metal layer 445 and the color filter 440, a planarization layer 460 is formed on the source/drain metal layer 450 to cover the color filter 440, and a pixel electrode layer 470 is formed on the planarization layer 460 and a part of the pixel electrode layer 470 penetrates the planarization layer 460 to connect with corresponding position of the source/drain metal layer 450. The structure of the third embodiment of the present invention also can be used to improve that of the above-mentioned prior art. By filling a metal layer in the contact well penetrating the color filter and the insulating oxide layer, metal contact resistance between pixel electrode layer and thin film transistor in the third embodiment of the present invention can be greatly reduced thus color display quality and useful life of the organic light emitting diode is improved. Further, before forming the pixel electrode layer 470 in the structure of the third embodiment of the present invention, a metal layer (not shown in FIG. 4) also can be filled, as the structure of the first embodiment of the present invention, in a contact well which penetrates the planarization layer 460 to connect with the source/drain metal layer 450. Then, the pixel electrode layer 470 is formed on the metal layer and the planarization layer 460 for reducing much more metal contact resistance between pixel electrode layer and thin film transistor. As mentioned previously, since the color filter is generally a negative photoresist, the photomask pattern for defining the color filter is the same with the metal pattern for filling in the contact well. Therefore, the present invention merely uses one common photomask of the color filter and needs no additional photomask.

The method of manufacturing the third embodiment of the present invention for improving contact resistance of an organic light emitting diode integrated with a color filter, comprising the following steps:
(a) providing a substrate;
(b) forming a poly-silicon island on the substrate;
(c) forming an insulating oxide layer on the substrate to cover the poly-silicon island;
(d) forming a gate metal layer corresponding to the central position of the poly-silicon island on the insulating oxide layer;
(e) forming a color filter on the insulating oxide layer to cover the gate metal layer;
(f) forming multiple contact wells on the color filter, wherein the contact wells penetrate the color filter and the insulating oxide layer;
(g) forming a metal layer on the color filter, wherein a part of the metal layer fills the contact wells and penetrates the color filter and the insulating oxide layer to connect with corresponding positions of the poly-silicon island;
(h) forming a source/drain metal layer on the metal layer and the color filter;
(i) forming a planarization layer on the color filter to cover the source/drain metal layer;
(j) forming a contact well on the planarization layer, wherein the contact well penetrates the planarization layer; and
(k) forming a pixel electrode layer on the planarization layer, wherein a part of the pixel electrode layer fills the contact well and penetrates the planarization layer to connect with corresponding position of the source/drain metal layer.

Further, before step (k) of forming a pixel electrode layer in the third embodiment of the present invention, a metal layer (not shown in FIG. 4) also can be filled, as the first embodiment of the present invention, in the contact well which penetrates the planarization layer to connect with the source/drain metal layer. Then, a pixel electrode layer is formed on the metal layer and the planarization layer for reducing much more metal contact resistance between pixel electrode layer and thin film transistor.

In addition, the planarization layer formed in the invention can be made of an organic material or an inorganic material. The dielectric layer also can be made of an organic material or an inorganic material. The poly-silicon island can be made of any semiconductor material. The substrate can be made of plastic, glass, quartz, or silicon wafer. The metal layer to be filled in the contact wells can be made of any metal with low resistance or organic conductive material and can be a multi-layer structure.

In summary, the present invention provides a structure and method for improving contact resistance of an organic light emitting diode integrated with a color filter, the structure and method mainly utilize a metal to be filled in a contact well on a source/drain metal layer or in a contact well corresponding to the position of the source/drain metal layer on a poly-silicon island to effectively reduce the contact resistance between pixel electrode and thin film transistor, therefore color display quality of the organic light emitting diode is improved.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

1. A structure for improving contact resistance of an organic light emitting diode integrated with a color filter, comprising:
a substrate;
a poly-silicon island formed on the substrate;
an insulating oxide layer formed on the substrate to cover the poly-silicon island;
a gate metal layer corresponding to the central position of the poly-silicon island formed on the insulating oxide layer;
a dielectric layer formed on the insulating oxide layer to cover the gate metal layer, wherein multiple contact wells are formed on the dielectric layer and the contact wells penetrate the dielectric layer and the insulating oxide layer;
a source/drain metal layer formed on the dielectric layer, wherein a part of the source/drain metal layer fills the contact wells and penetrates the dielectric layer and the insulating oxide layer to connect with corresponding position of the poly-silicon island;
a color filter formed on the source/drain metal layer;
a planarization layer formed on the color filter, wherein a contact well is formed on the planarization layer and the contact well penetrates the planarization layer and the color filter;
a metal layer formed on the planarization layer, wherein a part of the metal layer fills the contact well and penetrates the planarization layer and the color filter to connect with corresponding position of the source/drain metal layer; and
a pixel electrode layer formed on the metal layer and the planarization layer.

2. The structure for improving contact resistance of an organic light emitting diode integrated with a color filter of claim 1, wherein the planarization layer is made of an organic material or an inorganic material.

3. The structure for improving contact resistance of an organic light emitting diode integrated with a color filter of claim 1, wherein the dielectric layer is made of an organic material or an inorganic material.

4. The structure for improving contact resistance of an organic light emitting diode integrated with a color filter of claim 1, wherein the poly-silicon island is made of any semiconductor material.

5. The structure for improving contact resistance of an organic light emitting diode integrated with a color filter of claim 1, wherein the substrate is made of plastic, glass, quartz, or silicon wafer.

6. The structure for improving contact resistance of an organic light emitting diode integrated with a color filter of claim 1, wherein the metal layer to be filled in the contact wells is made of any metal with low resistance or organic conductive material and is a multi-layer structure.

7. A method for improving contact resistance of an organic light emitting diode integrated with a color filter, comprising:
(a) providing a substrate;
(b) forming a poly-silicon island on the substrate;
(c) forming an insulating oxide layer on the substrate to cover the poly-silicon island;
(d) forming a gate metal layer corresponding to the central position of the poly-silicon island on the insulating oxide layer;
(e) forming a dielectric layer on the insulating oxide layer to cover the gate metal layer;
(f) forming multiple contact wells on the dielectric layer, wherein the contact wells penetrate the dielectric layer and the insulating oxide layer;
(g) forming a source/drain metal layer on the dielectric layer, wherein a part of the metal layer fills the contact wells and penetrates the dielectric layer and the insulating oxide layer to connect with corresponding positions of the poly-silicon island;
(h) forming a color filter on the source/drain metal layer;
(i) forming a planarization layer on the color filter;
(j) forming a contact well on the planarization layer, wherein the contact well penetrates the planarization layer and the color filter;
(k) forming a metal layer on the planarization layer, wherein a part of the metal layer fills the contact well and penetrates the planarization layer and the color filter to connect with corresponding position of the source/drain metal layer; and
(l) forming a pixel electrode layer on the metal layer and the planarization layer.

8. The method for improving contact resistance of an organic light emitting diode integrated with a color filter of claim 7, wherein the planarization layer is made of an organic material or an inorganic material, the dielectric layer is made of an organic material or an inorganic material, the poly-silicon island is made of any semiconductor material, and the substrate is made of plastic, glass, quartz, or silicon wafer.

9. The method for improving contact resistance of an organic light emitting diode integrated with a color filter of claim 7, wherein the metal layer to be filled in the contact wells is made of any metal with low resistance or organic conductive material and is a multi-layer structure.

10. A structure for improving contact resistance of an organic light emitting diode integrated with a color filter, comprising:
a substrate;
a poly-silicon island formed on the substrate;
an insulating oxide layer formed on the substrate to cover the poly-silicon island;
a gate metal layer corresponding to the central position of the poly-silicon island formed on the insulating oxide layer;
a color filter formed on the insulating oxide layer to cover the gate metal layer;
a planarization layer formed on the color filter, wherein multiple contact wells are formed on the planarization layer and the contact wells penetrate the planarization layer, the color filter and the insulating oxide layer;
a metal layer formed on the planarization layer, wherein a part of the metal layer fills the contact wells and penetrates the planarization layer, the color filter and the insulating oxide layer to connect with corresponding positions of the poly-silicon island; and
a pixel electrode layer formed on the metal layer and the planarization layer.

11. The structure for improving contact resistance of an organic light emitting diode integrated with a color filter of claim 10, wherein the planarization layer is made of an organic material or an inorganic material.

12. The structure for improving contact resistance of an organic light emitting diode integrated with a color filter of claim 10, wherein the poly-silicon island is made of any semiconductor material.

13. The structure for improving contact resistance of an organic light emitting diode integrated with a color filter of claim 10, wherein the substrate is made of plastic, glass, quartz, or silicon wafer.

14. The structure for improving contact resistance of an organic light emitting diode integrated with a color filter of claim 10, wherein the metal layer to be filled in the contact wells is made of any metal with low resistance or organic conductive material and is a multi-layer structure.

15. A method for improving contact resistance of an organic light emitting diode integrated with a color filter, comprising:
(a) providing a substrate;
(b) forming a poly-silicon island on the substrate;
(c) forming an insulating oxide layer on the substrate to cover the poly-silicon island;
(d) forming a gate metal layer corresponding to the central position of the poly-silicon island on the insulating oxide layer;
(e) forming a color filter on the insulating oxide layer to cover the gate metal layer;
(f) forming a planarization layer on the color filter;
(g) forming multiple contact wells on the planarization layer, wherein the contact wells penetrate the planarization layer, the color filter, and the insulating oxide layer;
(h) forming a metal layer on the planarization layer, wherein a part of the metal layer fills the contact wells and penetrates the planarization layer, the color filter and the insulating oxide layer to connect with corresponding positions of the poly-silicon island; and
(i) forming a pixel electrode layer on the planarization layer.

16. The method for improving contact resistance of an organic light emitting diode integrated with a color filter of claim 15, wherein the planarization layer is made of an organic material or an inorganic material, the poly-silicon island is made of any semiconductor material, and the substrate is made of plastic, glass, quartz, or silicon wafer.

17. The method for improving contact resistance of an organic light emitting diode integrated with a color filter of claim 15, wherein the metal layer to be filled in the contact wells is made of any metal with low resistance or organic conductive material and is a multi-layer structure.

18. A structure for improving contact resistance of an organic light emitting diode integrated with a color filter, comprising:
a substrate;
a poly-silicon island formed on the substrate;
an insulating oxide layer formed on the substrate to cover the poly-silicon island;
a gate metal layer corresponding to the central position of the poly-silicon island formed on the insulating oxide layer;
a color filter formed on the insulating oxide layer to cover the gate metal layer, wherein multiple contact wells are formed on the color filter and the contact wells penetrate the color filter and the insulating oxide layer;
a metal layer formed on the color filter, wherein a part of the metal layer fills the contact wells and penetrates the color filter and the insulating oxide layer to connect with corresponding positions of the poly-silicon island;
a source/drain metal layer formed on the metal layer and the color filter;
a planarization layer formed on the source/drain metal layer to cover the color filter, wherein a contact well is formed on the planarization layer and the contact well penetrates the planarization layer;
a pixel electrode layer formed on the planarization layer, wherein a part of the pixel electrode layer fills the contact well and penetrates the planarization layer to connect with corresponding position of the source/drain metal layer.

19. The structure for improving contact resistance of an organic light emitting diode integrated with a color filter of claim 18, wherein the pixel electrode layer is replaced by the following:
a metal layer formed on the planarization layer, wherein a part of the metal layer fills the contact well and penetrates the planarization layer to connect with corresponding position of the source/drain metal layer; and
a pixel electrode layer formed on the metal layer and the planarization layer.

20. The structure for improving contact resistance of an organic light emitting diode integrated with a color filter of claim 18, wherein the planarization layer is made of an organic material or an inorganic material.

21. The structure for improving contact resistance of an organic light emitting diode integrated with a color filter of claim 18, wherein the poly-silicon island is made of any semiconductor material.

22. The structure for improving contact resistance of an organic light emitting diode integrated with a color filter of claim 18, wherein the substrate is made of plastic, glass, quartz, or silicon wafer.

23. The structure for improving contact resistance of an organic light emitting diode integrated with a color filter of claim 18, wherein the metal layer to be filled in the contact wells is made of any metal with low resistance or organic conductive material and is a multi-layer structure.

24. A method for improving contact resistance of an organic light emitting diode integrated with a color filter, comprising:
(a) providing a substrate;
(b) forming a poly-silicon island on the substrate;
(c) forming an insulating oxide layer on the substrate to cover the poly-silicon island;
(d) forming a gate metal layer corresponding to the central position of the poly-silicon island on the insulating oxide layer;
(e) forming a color filter on the insulating oxide layer to cover the gate metal layer;
(f) forming multiple contact wells on the color filter, wherein the contact wells penetrate the color filter and the insulating oxide layer;
(g) forming a metal layer on the color filter, wherein a part of the metal layer fills the contact wells and penetrates the color filter and the insulating oxide layer to connect with corresponding positions of the poly-silicon island;
(h) forming a source/drain metal layer on the metal layer and the color filter;
(i) forming a planarization layer on the color filter to cover the source/drain metal layer;
(j) forming a contact well on the planarization layer, wherein the contact well penetrates the planarization layer; and
(k) forming a pixel electrode layer on the planarization layer, wherein a part of the pixel electrode layer fills the contact well and penetrates the planarization layer to connect with corresponding position of the source/drain metal layer.

25. The method for improving contact resistance of an organic light emitting diode integrated with a color filter of claim 24, wherein the step (k) is replaced by the following: forming a metal layer on the planarization layer, wherein a part of the metal layer fills the contact well and penetrates the planarization layer to connect with corresponding position of the source/drain metal layer; and
forming a pixel electrode layer on the metal layer and the planarization layer.

26. The method for improving contact resistance of an organic light emitting diode integrated with a color filter of claim 24, wherein the planarization layer is made of an organic material or an inorganic material, the poly-silicon island is made of any semiconductor material, and the substrate is made of plastic, glass, quartz, or silicon wafer.

27. The method for improving contact resistance of an organic light emitting diode integrated with a color filter of claim 24, wherein the metal layer to be filled in the contact wells is made of any metal with low resistance or organic conductive material and is a multi-layer structure.
